(19) United States
(12) Patent Application Publication
(10) Pub. No.: US 2008/0281537 A1
(43) Pub. Date: Nov. 13, 2008

(54) Process for Measuring the Impedance of Electronic Circuits

(75) Inventors: Andrej Rumiantsev, Dresden (DE); Stojan Kanev, Sacka (DE)

Correspondence Address: HESLIN ROTHENBERG FARLEY & MESITI PC, 5 COLUMBIA CIRCLE, ALBANY, NY, 12203, US

(73) Assignee: SUSS MICROTEC TEST SYSTEMS GMBH, Sacka (DE)

(21) Appl. No.: 11/695,724

(22) Filed: Apr. 3, 2007

(30) Foreign Application Priority Data
Apr. 3, 2006 (DE) 10 2006 015 849.0

(51) Int. Cl. G01R 27/02

(52) U.S. Cl. 702/65

(57) ABSTRACT

The task underlying the invention, which concerns a method for measurement of impedance of electronic circuits, in which the input of the electronic circuit is acted upon by a high-frequency ac voltage with a measurement frequency f as test signal and from the reaction of the circuit to the test signal the impedance Z of the circuit is determined, in which a parameter S, which represents the value

$$S = \frac{Z - {Z}_{0}}{Z + {Z}_{0}}$$

at a stipulated reference impedance Z₀, is produced by means of an analyzer with a reference impedance Z₀, and from this parameter S the impedance Z is determined, is to minimize the error in measuring the impedances by determining parameter S. This is solved by the fact that the measurement frequency f is set so that a minimal error ΔZ is produced for Z.

The invention concerns a method for measurement of impedance of electronic circuits in which the input of the electronic circuit is acted upon with a high-frequency ac voltage with a measurement frequency f as test signal and from the reaction of the circuit to the test signal the impedance Z of the circuit is determined, in which a parameter S, which represents the value

$$S = \frac{Z - {Z}_{0}}{Z + {Z}_{0}}$$

at a stipulated reference impedance Z₀, is produced by means of an analyzer with a reference impedance Z₀, and the impedance Z is determined from this parameter S with

$$Z = {Z}_{0} \frac{1 + S}{1 - S} .$$

Both during the production process of electronic components and functional testing at the end of the production process it is often necessary to measure impedances of electronic circuits within an electronic component. A circuit arrangement being tested is ordinarily referred to as DUT (device under test).

Such impedances can be obtained as pure ohmic resistances R. Generally the impedances Z, however, are complex in nature, as expressed in the relation Z=R+jX, in which R is the real part (resistance) and X the imaginary part (reactance).

For example, the impedance of the circuit is determined by a capacitance C. If only capacitance has an effect on the impedance, then the real part equals zero. The impedance Z is then calculated as follows:

$$Z = - j \frac{1}{2 π fC} .$$

Ordinarily capacitance measurement occurs by acting on the circuit or circuit input with a dc voltage or ac voltage up to 30 MHz. The magnitude of the capacitance can be determined by means of the time behavior of the measurement voltage.

The increasing miniaturization during production of electronic components has meant that dielectrics are becoming increasingly thinner. This means that the leakage currents through the dielectric are becoming larger. Such leakage currents have the drawback that they distort the measurement result for capacitance measurement. This is described in “Evaluation of MOS Capacitor Oxide C-V Characteristics Using the Agilent 4294A,” Agilent Technologies, Inc., 2002, 5988-5102EN and especially page 29 there.

To counter this problem, impedances are increasingly being measured at higher frequencies in the range above 100 MHz. This means that the propagation region of the voltage in the capacitance is changed so that only the electromagnetic field still acts there and the leakage currents are minimized so that no electron loss occurs. The transmission and/or reflection factor is then measured (similarly to light). The ratio of transmitted and received wave magnitudes is then formed from the transmitted and received wave and produced as parameter S. This method is described in the presentation of different additional measurement methods in “Integrating high-frequency capacitance measurement for monitoring process variation of equivalent oxide thickness of ultrathin gate dielectrics,” Keithley Instruments Inc., 2004, No. 24744041KGW. It is assumed that the measurement error on the reference impedance Z₀ is minimal.

This type of measurement ordinarily occurs in a vector-network analyzer. These measurement instruments have a known error ΔS for parameter S. However, it has been shown that, contrary to the assumption in the prior art, the error minimum does not lie constantly at the same reference impedance. Instead, for a specific DUT this error ΔS is also dependent on the measurement frequency so that the measurement results obtained in this way are only marginally suitable.

Determination of ΔS ordinarily occurs with a method as described in EA-10/12-EA Guidelines on the Evaluation of Vector Network Analyzers (VNA), European Cooperation for Accreditation, May 2000 and in Application Note “What is your Measurement Accuracy? Vector Network Analyzer,” Anritsu Microwave Measurement Division, Morgan Hill, Calif., September 2001.

The task of the invention now consists of minimizing the error during measurement of impedances by determining parameter S.

This task is solved according to the invention with the features of Claim 1. The dependent Claims 2 to 1 [sic] provide favorable embodiments of the method according to the invention.

The invention is further described below by means of a practical example. This practical example pertains to capacitance measurement in MOSFET with thin gate oxides.

In the corresponding drawings

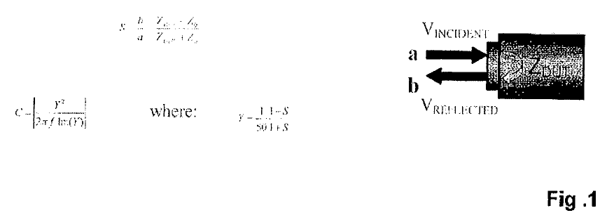

FIG. 1 shows a diagram of the measurement of the circuit with a vector network analyzer with determination of the capacitance C,

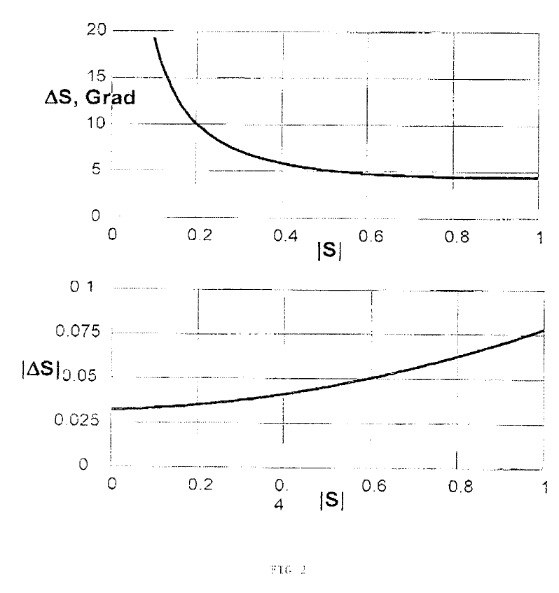

FIG. 2 shows the trend of the real and imaginary part of the error ΔS on the vector network analyzer (VNA),

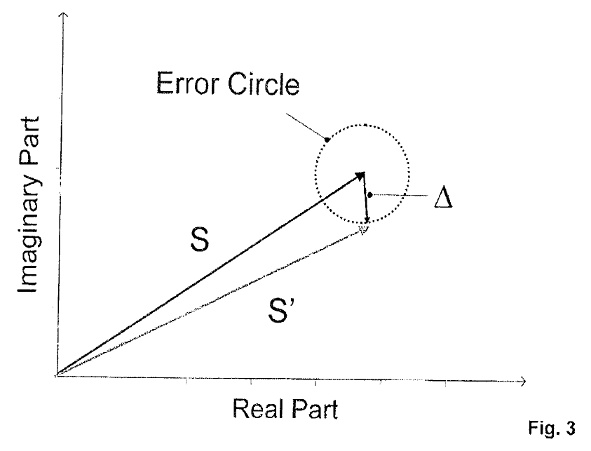

FIG. 3 shows a diagram of the appearance of the error ΔS,

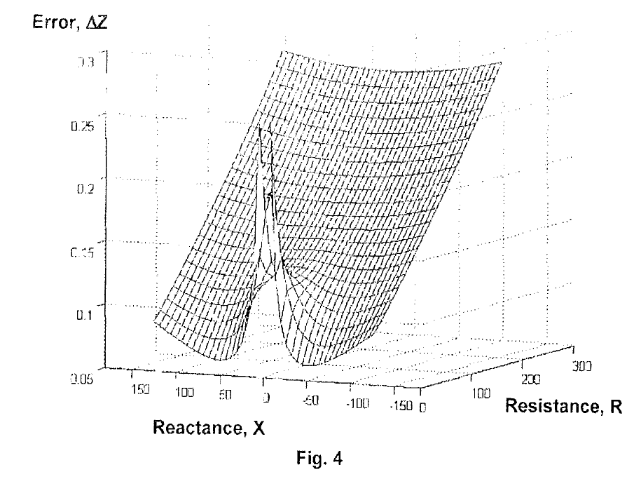

FIG. 4 shows a graph of the occurring error ΔZ of the impedance Z being measured in a complex plot,

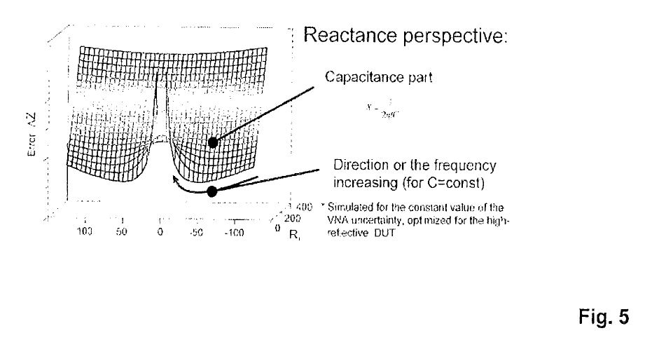

FIG. 5 shows an excerpt from FIG. 4 relative to the imaginary part,

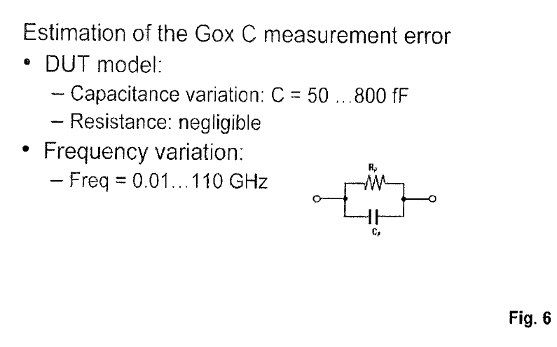

FIG. 6 shows a diagram of the replacement circuit of the impedance being measured and the parameter to be expected,

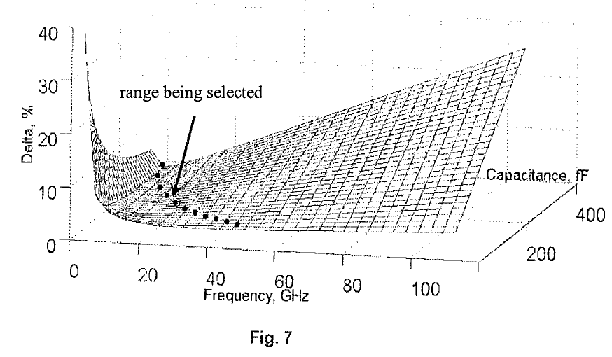

FIG. 7 shows a plot of the measurement frequency f to be chosen as a function of the capacitance to be expected and to achieve the least possible measurement error.

By means of a vector network analyzer (VNA) an impedance Z_{DUT} of an electronic circuit (not further shown) within an electronic component (DUT=device under test) is determined via parameter S, as shown in FIG. 1. The actual parameters of the DUT are Z_{DUT}=R+jX and

$${S}_{DUT} = \frac{R + j X - {Z}_{0}}{R + j X + {Z}_{0}} .$$

The measured impedance value is

$${Z}_{meas} = {Z}_{0} \frac{1 + {S}_{meas}}{1 - {S}_{meas}} .$$

As shown in FIG. 2, the vector network analyzer (VNA) has an error ΔS that also causes an error in the impedance ΔZ being measured. Because of the error ΔS, Sₘₑₐₛ=S_{DUT}+ΔS is obtained and therefore

$${Z}_{meas} = {Z}_{0} \frac{1 + ( {S}_{DUT} + Δ S )}{1 - ( {S}_{DUT} + Δ S )} .$$

The error for the impedance

$$Δ Z = \frac{\vert {Z}_{DUT} - {Z}_{meas} \vert}{\vert {Z}_{DUT} \vert}$$

follows from this.

FIG. 3 shows the effects of complexity of the error ΔS on the measurement result.

It is found that the impedance Z_{DUT} being measured is dependent on the measurement frequency. The parameter S of the circuit being measured is also dependent on the impedance Z_{DUT} being measured. Consequently, the measurement accuracy of the vector network analyzer depends on parameter S.

As shown in FIGS. 4 to 6, an estimate of error ΔS occurs according to the invention at different frequencies.

As is apparent from FIG. 7, the measurement frequency f should be chosen relative to the expected capacitances C from the marked area of the diagram in order to be able to determine the capacitance as precisely as possible.

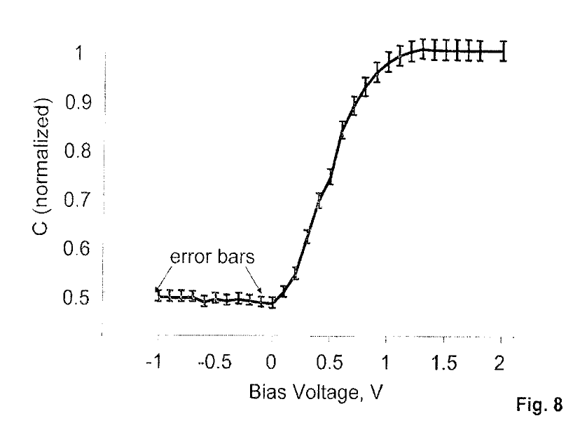

As shown in FIG. 8, it is also possible with the method according to the invention to state the error range (error bars) in which the achieved measurement result fluctuates.

1. Method for measurement of impedance of electronic circuits, in which the input of the electronic circuit is acted upon by a high-frequency ac voltage with a measurement frequency f as test signal and from the reaction of the circuit to the test signal the impedance Z of the circuit is determined, in which a parameter S, which represents the value
$$S = \frac{Z - {Z}_{0}}{Z + {Z}_{0}}$$
at a stipulated reference impedance Z₀, is produced by means of an analyzer with a reference impedance Z₀ and from this parameter S the impedance Z is determined with
$$Z = {Z}_{0} \frac{1 + S}{1 - S} ,$$
characterized by the fact that the measurement frequency f is set so that a minimal error ΔZ is obtained for Z by
determining a value Zₑ of the impedance of the circuit to be expected with reference to the known characteristics of the circuit,
calculating with
$${S}_{e} ( f ) = \frac{{Z}_{e} ( f ) - {Z}_{0}}{{Z}_{e} ( f ) + {Z}_{0}}$$
the expected value Sₑ of the parameter S,
determining from the instrument-specific error curve ΔS=func(S) known for the analyzer the corresponding error value ΔSₑ=func(Sₑ) for value Sₑ,
calculating from the relation
$$Δ {Z}_{e} ( f ) = {Z}_{0} \frac{1 + Δ {S}_{e} ( f )}{1 - Δ {S}_{e} ( f )}$$
for different values of the measurement frequency f of the frequency-dependent error value ΔZₑ(f) the impedance Zₑ to be expected and
setting the measurement frequency f at a value at which the error value ΔZₑ(f) of the impedance Zₑ to be expected has a minimum.

2. Method according to claim 1, characterized by the fact that the impedance, which depends on the voltage V lying on it, is measured, characterized by the fact that, depending on voltage V, the measurement frequency f is set so that a minimal error ΔZ is obtained for Z by
determining the expected value Zₑ(V) of the impedance in the circuit by means of the known characteristics of the circuit,
calculating with
$${S}_{e} ( V ; f ) = \frac{{Z}_{e} ( V ; f ) - {Z}_{0}}{{Z}_{e} ( V ; f ) + {Z}_{0}}$$
the values Sₑ(V) to be expected for parameter S,
determining from an instrument-specific error curve ΔS=func(S) known for the analyzer the error value ΔSₑ=func(Sₑ) corresponding for a value Sₑ,
calculating from the relation
$$Δ {Z}_{e} ( f ; V ) = {Z}_{0} \frac{1 + Δ {S}_{e} ( f ; V )}{1 - Δ {S}_{e} ( f ; V )} ,$$
for different values of measurement frequency f and for different values of voltage V, the frequency-dependent error value ΔZₑ(f; V) of the expected impedance Zₑ and setting the measurement frequency f as a function of the voltage over the capacitance to a value at which the error value ΔZₑ(f; V) of the expected impedance Zₑ has a minimum.

3. Method according to claim 1 or 2, characterized by the fact that the impedance Zₑ to be expected is determined from an impedance substitution circuit of the circuit.

4. Method according to one of the claims 1 to 3, characterized by the fact that the impedance is formed essentially by a capacitance and the magnitude of the capacitance is determined by the impedance.

5. Method according to claim 4, characterized by the fact that the expected impedance is calculated with a stipulated calculation frequency f_{b} and a calculated or simulated value Cₑ that is expected for capacitance C from
$${Z}_{e} = - j \frac{1}{2 π {f}_{b} {C}_{e}} .$$

6. Method according to one of the claims 1 to 5, characterized by the fact that determination of the setting of the measurement frequency is repeated and the frequency determined during the repeated run is used as measurement frequency, in which during repeated determination the impedance Z measured after the first measurement frequency determination is used as the expected value Zₑ during repetition of the determination.
